(19) United States
(12) Patent Application Publication
(10) Pub. No.: US 2014/0112065 A1
(43) Pub. Date: Apr. 24, 2014

(54) SEMICONDUCTOR MEMORY DEVICE

(71) Applicant: FUJITSU SEMICONDUCTOR LIMITED, Yokohama (JP)

(72) Inventor: Ryo TANABE, Kawasaki (JP)

(73) Assignee: FUJITSU SEMICONDUCTOR LIMITED, Yokohama (JP)

(21) Appl. No.: 14/043,355

(22) Filed: Oct. 1, 2013

(30) Foreign Application Priority Data
Oct. 24, 2012 (JP) 2012-234762

(51) Int. Cl. G11C 11/419

(52) U.S. Cl. CPC G11C 11/419
USPC 365/154

(57) ABSTRACT

A semiconductor memory device including a memory cell of static type; a word line connected to the memory cell; a word driver driving the word line; and a compensating circuit including a first transistor of N-channel type having a drain connected to the word line and a source to be connected to a ground potential, and a control circuit connected to the first transistor and changing the first transistor from an OFF state to an ON state based on a rise of an ambient temperature or a rise of a power source voltage to thereby lower a voltage of the word line.

### CROSS-REFERENCE TO RELATED APPLICATION

This application is based upon and claims the benefit of priority of the prior Japanese Patent Application No. 2012-234762, filed on Oct. 24, 2012, the entire contents of which are incorporated herein by reference.

### FIELD

The embodiments discussed herein are related to a semiconductor memory device.

### BACKGROUND

The semiconductor memory device including static memory cells, i.e., SRAM (Static Random Access Memory) has the operation margin decreased as is more micronized.

In the SRAM, when the word line connected to a memory cell to be selected is activated, the gates of the transistors of the memory cells arranged in the same row as said memory cell are opened. Accordingly, there is a risk that when the ambient temperature is relatively high, or the power source voltage is relatively high, the information stored in the memory cells not be selected may be broken.

Such information breakage tends to occur when the potential of the word lines at the time when they are activated is relatively high. It is proposed to set the potential of the word line at the time when they are activated is set relatively low.

Related references are as follows:
Japanese Laid-open Patent Publication No. 2007-66493;
Japanese Laid-open Patent Publication No. 2008-65968; and
Japanese Laid-open Patent Publication No. 2011-54255.

### SUMMARY

According to an aspect of embodiments, a semiconductor memory device including a memory cell of static type; a word line connected to the memory cell; a word driver driving the word line; and a compensating circuit including a first transistor of N-channel type having a drain connected to the word line and a source to be connected to a ground potential, and a control circuit connected to the first transistor and changing the first transistor from an OFF state to an ON state based on a rise of an ambient temperature or a rise of a power source voltage to thereby lower a voltage of the word line.

According to another aspect of the embodiments, a semiconductor memory device including a memory cell of static type; a word line connected to the memory cell; a word driver driving the word line; and a compensating circuit including a first transistor of N-channel type having a gate and a drain connected to the word line, and a second transistor of N-channel type having a gate and a drain connected to a source of the first transistor and a source to be connected to a ground potential.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIG. 1 is a circuit diagram of a semiconductor memory device according to a first embodiment;

FIG. 2 is a circuit diagram of a semiconductor memory device according to a control;

FIGS. 3A to 3E are results of simulations (Part 1) of the semiconductor memory device according to the first embodiment;

FIGS. 4A to 4E are results of simulations of a reduction of a potential of a word line in a semiconductor memory device according to the control.

FIGS. 5A to 5E are results of simulations (Part 2) of the semiconductor memory device according to the first embodiment;

FIG. 6 is a circuit diagram of a semiconductor memory device according to a second embodiment;

FIGS. 7A to 7E are results of simulations of the semiconductor memory device according to the second embodiment;

FIG. 8 is a circuit diagram of a semiconductor memory device according to a third embodiment; and

FIG. 9 is a graph of a result of a simulation of the semiconductor memory device according to the third embodiment.

### DESCRIPTION OF EMBODIMENTS

Simply setting the potential of the word lines low causes excessive decreases of the read speed and the write speed when the ambient temperature and the power source voltage are relatively low.

### [a] First Embodiment

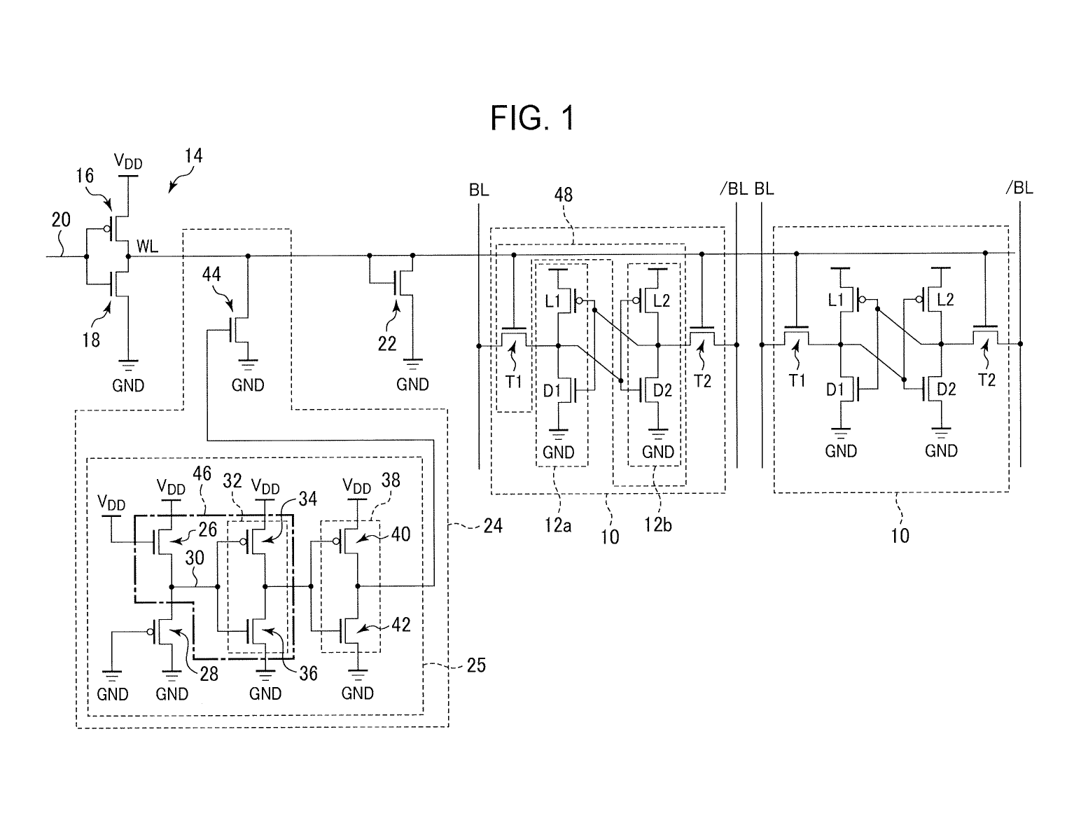

The semiconductor memory device according to a first embodiment of the present invention will be described with reference to FIGS. 1 to 5E. FIG. 1 is the circuit diagram of the semiconductor memory device according to the present embodiment.

A plurality of static memory cells 10 of static type are arranged in a matrix. The plural memory cells 10 are arranged not only row-wise (horizontally as viewed in FIG. 1) but also column-wise (vertically as viewed in FIG. 1), but it is omitted suitably in FIG. 1.

Each static memory cell 10 comprises a flip-flop circuit including two CMOS inverters 12a, 12b each formed by a P-channel transistor L1, L2 and an N-channel transistors D1, D2 complementarily connected with each other. Such P-channel transistors (P-channel type transistors, PMOS transistors) L1, L2 are called load transistors. Such N-channel transistors (N-channel type transistors, NMOS transistors) D1, D2 are called driver transistors.

The input terminal of the inverter 12a formed by the load transistor L1 and the driver transistor D2 is connected to the output terminal of the inverter 12b. The input terminal of the inverter 12b formed by the load transistor L2 and the driver transistor D2 are connected to the output terminal of the inverter 12a.

The inverter 12a receives the signal of the output terminal of the inverter 12b and outputs the logic inverted signal of the inputted signal. The inverter 12b receives the signal of the output terminal of the inverter 12a and outputs the logic inverted signal of the inputted signal.

The output terminal of the inverter 12a and the input terminal of the inverts 12b are connected to one of the source/drain of a transfer transistor T1 formed by an N-channel transistor. The other of the source/drain of the transfer transistor T1 is connected to a bit line BL.

The output terminal of the inverter 12b and the input terminal of the inerter 12a are connected to one of the source/drain of the a transfer transistor T2 formed by an N-channel transistor. The other of the source/drain of the transfer transistor T2 is connected to a bit line /BL.

The gates of the respective transfer transistors T1, T2 are connected to a word line WL.

The gates of the transfer transistors T1, T2 of the plural memory cells 10 arranged in the same row are connected commonly by the same word line WL.

A plurality of the word line WL are actually formed, but in FIG. 1, one of the plural word lines WL is illustrated.

The other of the sources/drains of the transfer transistors T1, T2 of the plural memory cells 10 arranged in the same column are commonly connected by the same bit lines BL, /BL.

The word lines WL are respectively connected to the output terminals of a plurality of word drivers (driver circuits) 14 provided in a row decoder (not illustrated).

In FIG. 1, one of the plural word drivers 14 provided in the row decoder is illustrated.

The word driver 14 is formed by a P-channel transistor 16 and an N-channel transistor 18 serially connected. The source of the P-channel transistor 16 is connected to the power source voltage VDD. The rated voltage of the power source voltage VDD is, e.g., about 1.2 V. The source of the N-channel transistor 18 is connected to the ground voltage GND. The gate of the P-channel transistor 16 and the gate of the N-channel transistor 18 are connected to a signal line 20. The signal line 20 becomes L level when the word line WL is driven and becomes H level when the word line WL is not driven. The drain of the P-channel transistor 16 and the drain of the N-channel transistor 18, i.e., the output terminal of the word driver 14 is connected to the word line WL. The gate width of the P-channel transistor 16 is, e.g., about 9.6 μm. The gate width of the N-channel transistor 18 is, e.g., about 4.8 μm.

The gate width of the P-channel transistor 16 and N-channel transistor 18 is not limited to them and is suitably so set that the potential of the word line WL is required potentials in various cases.

The gate length of the transistors is set equal to each other and is, e.g., about 70 nm.

The respective bit lines BL, /BL are connected to a column decoder (not illustrated).

An N-channel transistor 22 is connected to each word line WL. The drain and the source of the N-channel transistor 22 are connected to the word line WL, and the source of the N-channel transistor 22 is connected to the ground potential GND. The N-channel transistor 22 is for lowering the potential of the word line WL. The potential of the word line WL is lowered by the N-channel transistor 22 alone in some cases and, in other cases, is lowered by the cooperation of the N-channel transistor 22 with a compensating circuit 24. The N-channel transistor suitably lowers the potential of the word line WL whether or not the compensating circuit 24 starts to operate. That is, the N-channel transistor 22 acts to set a basic reduction of the potential of the word line WL. A plurality of the N-channel transistor 22 are parallelly arranged. In FIG. 1, one of the plural parallelly arranged N-channel transistors 22 is illustrated. The N-channel transistors 22 parallelly arranged have the drains and the gates connected to the word lines WL and have the sources connected to the ground potential GND.

The gate width of the N-channel transistor 22 is, e.g., about 0.45 μm. The number of the parallelly arranged N-channel transistors 22 is, e.g., about six.

The gate width of the N-channel transistor 22 is not limited to 0.45 μm and can be suitably so set that the reduction of the potential of the word line WL is a required reduction. The number of the parallelly arranged N-channel transistors 22 is not limited to six either and is suitably so set that the reduction of the potential of the word line WL is a required reduction.

For example, the gate width of the N-channel transistor 22 and the number of the N-channel transistor 22 are so set that when the N-channel transistor 44 is OFF, and the output of the word driver 14 is H level, the reduction of the potential of the word line WL is, e.g., about 0.1 V.

The reduction of the potential of the word line WL at the time when the N-channel transistor 44 is OFF, and the output of the word driver 14 is H level is not limited to about 0.1 V and can be suitably set.

To each word line WL, the compensating circuit (auxiliary circuit, assist circuit) 24 is connected. The compensating circuit 24 is for lowering the potential of the word line WL in cooperation with the N-channel transistor 22. The compensating circuit 24 acts as an assist circuit which further lowers the voltage of the word line WL when a reduction of the voltage of the word line WL by the N-channel transistor 22 is insufficient.

The compensating circuit 24 includes the N-channel transistor 44 connected to the word line WL, and a control circuit 25 for controlling the N-channel transistor 44.

On the first stage of the control circuit 25, an N-channel transistor 26 and a P-channel transistor 28 serially connected is provided. The gate and the drain of the N-channel transistor 26 are connected to the power source voltage VDD. The gate and the drain of the P-channel transistor 28 are connected to the ground potential GND. The source of the N-channel transistor 26 and the source of the P-channel transistor 28, i.e., a node 30 is connected to the input terminal of an inverter 32 to be described later. The potential of the node 30 rises due to the rise of the ambient temperature and the increase of the power source voltage VDD. The potential of the node 30 is lower than the logic threshold potential of the inverter 32 when the ambient temperature and the power source voltage VDD are relatively low and becomes higher than the logic threshold potential of the inverter 32 when the ambient temperature and the power source voltage VDD are relatively high.

The logic threshold potential (logic inversion threshold value) of the inverter is an input potential of the inverter at the time when a logic output of the inverter is inverted.

The logic threshold potential is, e.g., about (the power source voltage VDD)/2 here.

With the N-channel transistor 26 provided on the side of the power source and the P-channel transistor 28 provided on the side of the ground, the control width of the potential of the node 30 is (VDD-Vthn-Vthp).

“Vthn” is a threshold voltage of the N-channel transistor 26, and “Vthp” is threshold voltage of the P-channel transistor 28.

The potential of the node 30 is neither the power source voltage VDD nor the ground potential GND and is the intermediate potential, which makes relatively easy to control the potential of the node 30.

With the N-channel transistor 26 provided on the side of the power source and the P-channel transistor 28 provided on the side of the ground, the through current is suppressed in comparison with the case that the P-channel transistor is provided on the side of the power source, and the N-channel transistor is provided on the side of the ground.

The potential of the node 30 can be adjusted by suitably setting the gate width of the N-channel transistor 26, the gate width of the P-channel transistor 28, etc. For example, increasing the gate width of the N-channel transistor 26 decreases the electric resistance between the source and the drain of the N-channel transistor 26, and the potential of the node 20 rises. On the other hand, decreasing the gate width of the N-channel transistor 26 increases the electric resistance between the source and the drain of the N-channel transistor 26, and the potential of the node 30 lowers. The gate width of the N-channel transistor 26, the gate width of the P-channel transistor 28, etc. are so set that the potential of the node 30 becomes a required potential.

On the second stage of the control circuit 25, an inverter 32 is provided. The inverter 32 is formed of a P-channel transistor 34 and an N-channel transistor 36 serially connected. The source of the P-channel transistor 36 is connected to the power source voltage VDD, and the source of the N-channel transistor 36 is connected to the ground potential GND. The drain of the P-channel transistor 34 and the drain of the N-channel transistor 36 are electrically connected to each other. The gate of the P-channel transistor 34 and the gate of the N-channel transistor 36, i.e., the input terminal of the inverter 34 is connected to the node 30 described above. The drain of the P-channel transistor 34 and the drain of the N-channel transistor 36, i.e., the output terminal of the inverter 32 is connected to the input terminal of an inverter 38 to be described later.

It is preferable that the inverter 32 of the control circuit 25 is more invertible than the inverters 12a, 12b of the memory cell 10 when the ambient temperature and the power source voltage VDD rise, so that the control circuit 25 is caused to operate to thereby sufficiently lower the potential of the word line WL to surely prevent the information stored in the memory cell 10 from being broken.

The stability of the static memory cell 10 depends on a current driving force radio (β ratio) between the transfer transistors T1, T2 and the driver transistors D1, D2. Such β ratio is expressed by Formula (1) described below.

β ratio=(current driving force of the driver transistor)/(current driving force of the transfer transistor) (1)

When the ambient temperature and the power source voltage VDD rise, the β ratio of the control circuit 25 is so set smaller than the β ratio of the memory cell 10 that the inverter 32 of the control circuit 25 is more invertible that the inverters 12a, 12b of the memory cell

The current driving force of the a transistor depends on the gate width of the transistor. That is, as the gate width of a transistor is larger, the current driving force of the transistor is larger.

The channel transistor 36 of the control circuit corresponds to the drive transistors D1, D2 of the memory cell 10. The N-channel transistor 26 of the control circuit 25 corresponds to the transfer transistors T1, T2 of the memory cell 10.

Accordingly, the β ratio of the control circuit is smaller as the gate width of the N-channel transistor 36 of the control circuit 25 is smaller and is smaller as the gate width of the N-channel transistor 26 of the control circuit 25 is larger.

The β ratio of the memory cell 10 is larger as the gate width of the driver transistors D1, D2 of the memory cell 10 is larger and is larger as the gate width of the transfer transistors T1, T2 of the memory cell 10 is smaller.

Accordingly, the gate width of the respective transistors is suitably set to satisfy the following formula (2) so that the inverter 32 of the control circuit 25 is more invertible than the inverters 12a, 12b of the memory cells 10 when the ambient temperature and the power source voltage VDD rise.

wcd/wct<wmd/wmt (2)

wherein “wcd” is the gate width of the N-channel transistor 36 of the control circuit 25; “wct” is the gate width of the N-channel transistor 26 of the control circuit 25; “wmd” is the gate width of the driver transistors D1, D2 of the memory cell 10; and “wmt” is the gate width of the transfer transistors T1, T2 of the memory cell 10.

The gate width wct of the N-channel transistor 26 of the control circuit 25 is set at, e.g., about 100 nm. The gate width wcd of the N-channel transistor 36 of the control circuit 25 is set at, e.g., about 100 nm. The gate width wcl of the P-channel transistor 34 of the control circuit 25 is set at, e.g., about 80 nm.

The gate width wmt of the transfer transistor T1, T2 of the memory cell 10 is set at, e.g., about 100 nm. The gate width wmd of the driver transistors D1, D2 of the memory cell 10 is set at, e.g., about 200 nm. The gate width wml of the load transistors L1, L2 of the memory cell 10 is set at, e.g., about 90 nm.

The gate width of these transistors is not limited to the above. The gate width of these transistors may be suitably so set that when the ambient temperature and the power source voltage VDD rise, the inverters 32 of the control circuit 25 is more invertible than the inverters 12a, 12b of the memory cell 10.

As described above, the ratio (β ratio) of the current driving force of the NMOS transistor 36 to the current driving force of the NMOS transistor 26 is set smaller than the ratio (β ratio) of the current driving force of the driver transistor D2 to the current driving force of the transfer transistor T1.

On the third stage of the control circuit 25, an inverter 38 is provided. The inverter 38 inverses the logic output of the inverter 32. The inverter 38 is formed by a P-channel transistor 40 and an N-channel transistor 42 serially connected. The source of the P-channel transistor 40 is connected to the power source voltage VDD. The source of the N-channel transistor 42 is connected to the ground potential GND. The gate of the P-channel transistor 40 and the gate of the N-channel transistor 42, i.e., the input terminal of the inverter 38 is connected to the output terminal of the inverter 32. The drain of the P-channel transistor 40 and the drain of the N-channel transistor 42, i.e., the output terminal of the inverter 38 is connected to the gate of an N-channel transistor (control gate) 44 to be described later.

The N-channel transistor 44 lowers the potential of the word line WL in cooperation with the N-channel transistor 22 when the ambient temperature and the power source voltage VDD are relatively high. A plurality of the N-channel transistor 44 are arranged, e.g., parallelly. In FIG. 1, one of the plural N-channel transistors 44 parallelly arranged is illustrated. The plural N-channel transistors 44 parallelly arranged have the drains respectively connected to the word line WL, have the gates connected to the output terminal of the inverter 38 and have the source connected to the ground potential GND.

The gate width of the N-channel transistor 44 is set at, e.g., about 0.45 μm. The number of the N-channel transistors 44 parallelly arranged is set at, e.g., about two.

The width of the N-channel transistor 44 is not essentially about 0.45 μm and is suitably so set that, when the N-channel transistor 44 is turned ON, the reduction of the potential of the word line WL is a desired reduction. The number of the N-channel transistors 44 parallelly arranged is not essential two and is suitably so set that when the N-channel transistor is turned ON, the reduction of the potential of the word line WL is a desired reduction.

The circuit 46 formed by the transistors 26, 34, 38 of the control circuit 25 corresponds to the circuit formed by the transistors T1, L2, D2 of the memory cell 10. However, the gate width of the N-channel transistor 26 of the control circuit 25 and the gate width of the transistor T1 of the memory cell 10 are not always equal to each other. The gate width of the P-channel transistor 34 of the control circuit 25 and the gate width of the load transistor L1 of the memory cell 10 are not always equal to each other. The gate width of the N-channel transistor 36 of the control circuit 25 and the gate width of the deriver transistor D1 of the memory cell 10 are not always equal to each other. Since the circuit 46 formed by the transistors 26, 34, 36 of the control circuit 25 corresponds to the circuit 48 formed by the transistors T1, L2, D2 of the memory cell 10, these circuits 46, 48 indicate similar operations. However, the circuit 46 formed by the transistors 26, 34, 36 of the control circuit 25 is more reactive to rises of the ambient temperature and the power source voltage VDD than the circuit 48 formed by the transistors T1, L2, D2 of the memory cell 10. Accordingly, when current tends to flow to the transfer transistor T1 of the memory cell 10 by relative rises of the ambient temperature and the power source voltage VDD and break the data stored in the memory cell 10, the control circuit 25 of the compensating circuit 24 surely operates. That is, when the stability of the memory cell 10 lowers, the N-channel transistor 22 and the compensating circuit 24 cooperate to sufficiently lower the potential of the word line WL and surely prevent the breakage of the data stored in the memory cell 10.

When the ambient temperature and the power source voltage VDD are relatively low, the potential of the node 30 is lower than the logic threshold potential of the inverter 32. Accordingly, the output of the inverter 32 is H level, and the output of the inverter 38 is L level. Accordingly, the N-channel transistor 44 connected to the word line WL is OFF. Accordingly, when the ambient temperature and the power source voltage VDD are relatively low, the potential of the word line WL is lowered by the N-channel transistor 22 alone.

On the other hand, when the ambient temperature and the power source voltage VDD become relatively high, the potential of the node 30 becomes higher than the logic threshold potential of the inverter 32. Thus, the P-channel transistor 34 of the inverter 32 is turned OFF, and the N-channel transistor 36 of the inverter 32 is turned ON. Then, the output of the inverter 32 becomes L level, and the output of the inverter 38 becomes H level. Then, the N-channel transistor 44 connected to the word line WL is turned ON. Thus, when the ambient temperature and the power source voltage VDD relatively rise, the N-channel transistor 22 and the N-channel transistor 44 of the compensating circuit 24 cooperate to lower the potential of the word line WL.

As described above, according to the present embodiment, the circuit 46 for sensing the stability of the memory cell 10 is provided in the compensating circuit 24 and the compensating circuit 24 operates when the ambient temperature and the power source voltage VDD become relatively high, and the stability of the memory cell 10 lowers. Accordingly, the voltage of the word line WL can be suitably lowered corresponding to the stability of the memory cell 10. When the ambient temperature and the power source voltage VDD are relatively low, the compensating circuit 24 does not operate, and the potential of the word line WL never excessively lowers, whereby the read speed, the write speed, etc. are never lowered.

To design the semiconductor memory device according to the present embodiment, simulations, e.g., Monte Carlo simulation or others is suitably made to give suitable values of the gate width of the transistors, etc.

Thus, the semiconductor memory device according to the present embodiment is constituted.

(Evaluation Result)

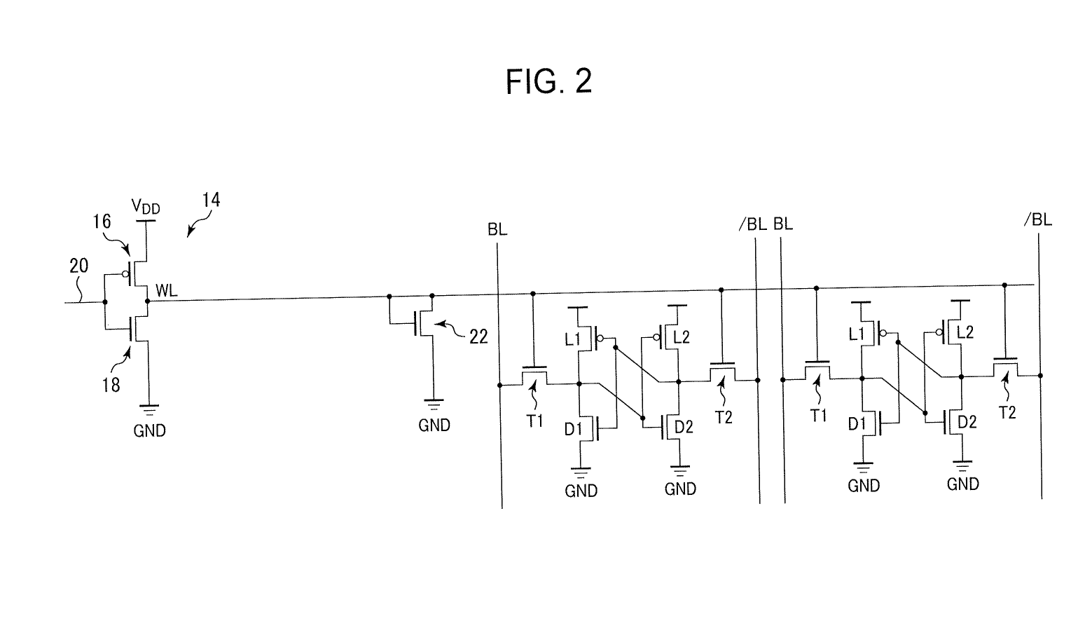

The result of the simulation of the semiconductor memory device according to the present embodiment will be explained with reference to FIGS. 2 to 5E.

FIG. 2 is the circuit diagram of a semiconductor memory device according to a control.

As illustrated in FIG. 2, in the semiconductor memory device according to the control does not include the compensating circuit 24 (see FIG. 1) as in the present embodiment, and the voltage of the word line WL is lowered by the N-channel transistor 22 alone.

In an example, i.e., in simulating the semiconductor memory device according to the present embodiment, six N-channel transistors 22 were arranged parallelly.

In simulating the semiconductor memory device according to the control, nine N-channel transistors 22 were parallelly arranged. In FIG. 2, one of the nine N-channel transistors 22 is illustrated.

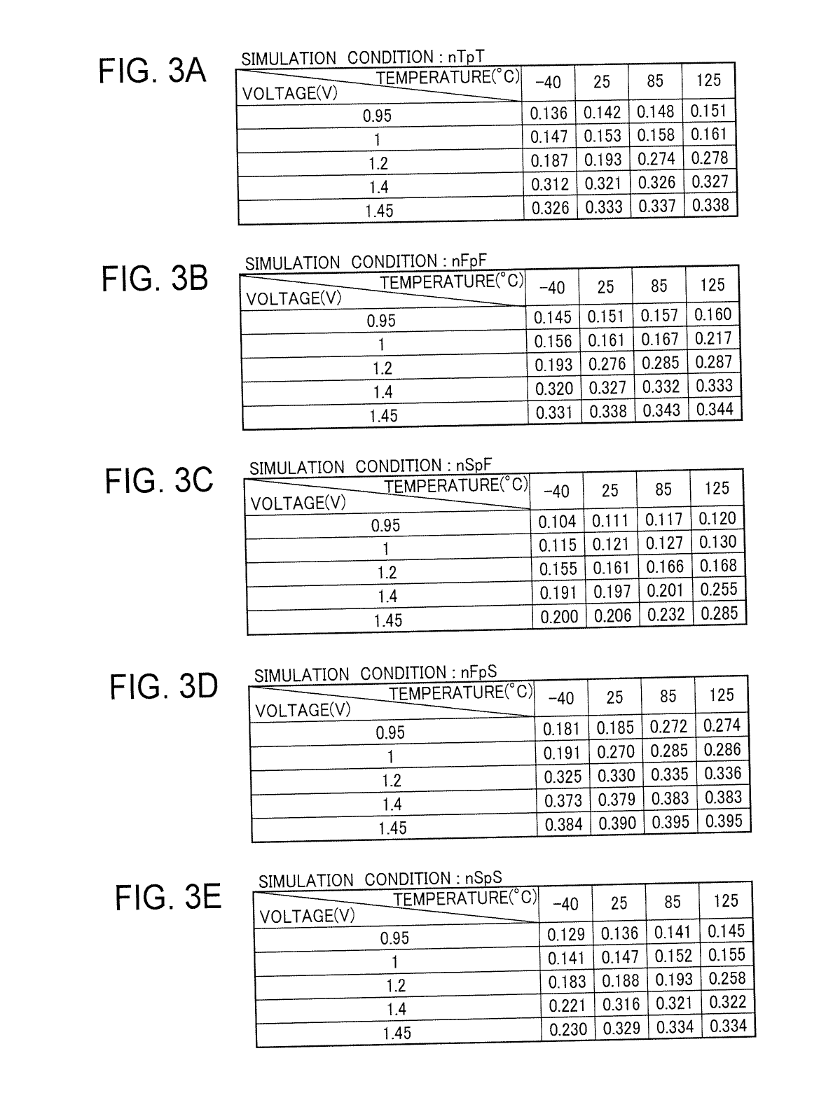

FIGS. 3A to 3E are the results of the simulation of the reductions of the potential of the word line in the semiconductor memory device according to the present embodiment.

FIG. 3A illustrates the case that the speed of the N-channel transistor and the speed of the P-channel transistor are standard. FIG. 3B illustrates the case that the speed of N-channel transistor is higher than standard, and the speed of the P-channel transistor is also higher than standard. FIG. 3C illustrates that the speed of the N-channel transistor is lower than standard, and the speed of the P-channel transistor is higher than standard. FIG. 3D illustrates the case that the speed of the N-channel transistor is higher than standard, and the speed of the P-channel transistor is lower than standard. FIG. 3E illustrates the case that both the speed of the N-channel transistor and the speed of the P-channel transistor are lower than standard.

Variation of the speed of transistors are caused by fluctuations of the manufacturing conditions.

The speed of transistors is higher as the drain current at the time when a prescribed bias voltage is applied is larger. The case that the volume of the drain current at the time when a prescribed bias voltage is applied is standard is called Typical (T), the case that the such drain current is larger than standard is called Fast (F), and the case that such drain current is smaller than standard is called Slow (S).

The sign “nT” represents that the speed of the N-channel transistor is standard, the sign “pT” represents that the speed of the P-channel transistor is standard. The sign “nF” represents that the speed of the N-channel transistor is higher than standard, and the signal “pF” represents that the speed of the P-channel transistor is higher than standard. The signal “nS” represents that the speed of the N-channel transistor is lower than standard, and the sign “pS” represents that the speed of the P-channel transistor is lower than standard.

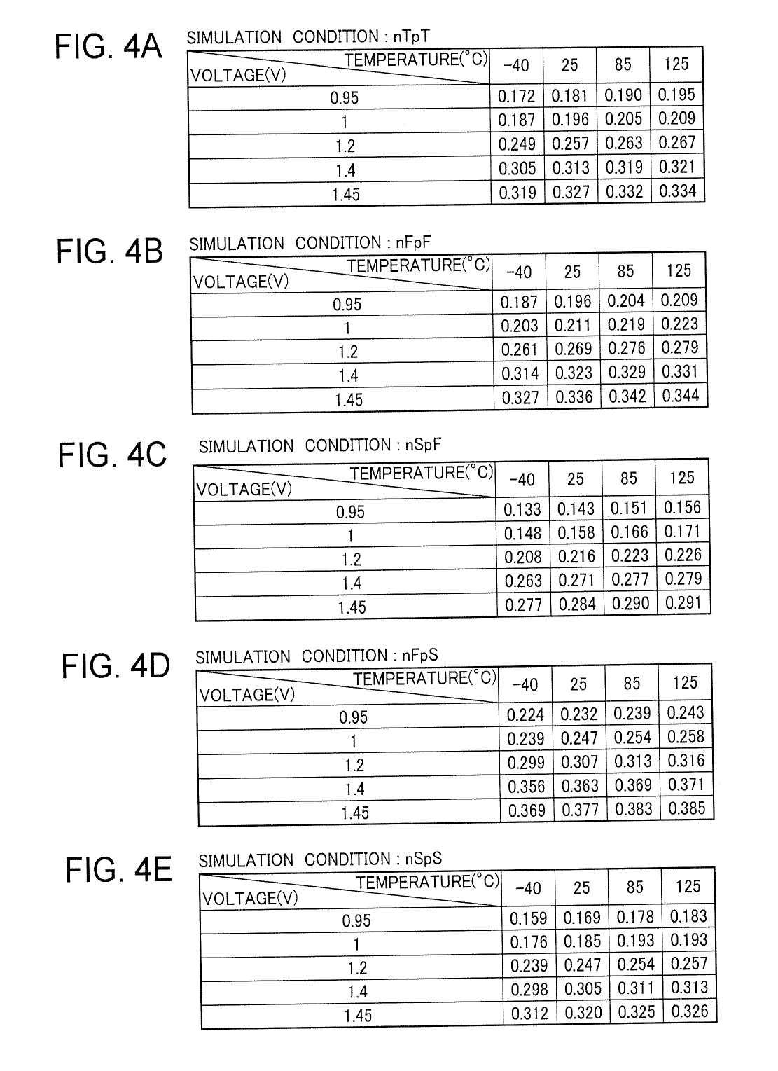

FIGS. 4A to 4E are the results of the simulations of the reduction of the potential of the word line in the semiconductor memory device according to the control.

FIG. 4A illustrates the case that both the speed of the N-channel transistor and the speed of the P-channel transistor are standard. FIG. 4B illustrates the case that the speed of the N-channel transistor and the speed of the P-channel transistor are higher than standard. FIG. 4C illustrates the case that the speed of the N-channel transistor is lower than standard, and the speed of the P-channel transistor is higher than standard. FIG. 4D illustrates the case that the speed of the N-channel transistor is higher than standard, and the speed of the P-channel transistor is lower than the standard. FIG. 4E illustrates the case that both the speed of the N-channel transistor and the speed of the P-channel transistor are lower than standard.

As seen in FIGS. 3A and 4A, when the ambient temperature is 25° C. (room temperature), and the power source voltage is 1.2 V (the rated voltage), the reduction of the potential of the word line WL in the example is smaller than by about 64 mV than the reduction of the potential in the word line WL in the control.

As seen in FIGS. 3A to 4E, under the condition that the ambient temperature is higher, and the power source voltage VDD is high, in the example, the potential of the word line WL sufficiently lowers as well as in the control. As illustrated, according to the present embodiment, under the condition where the stability of the memory cell 10 lowers, the potential of the word line WL sufficiently lowers, and the breakage of the information stored in the memory cell 10 can be surely prevented.

As illustrated in FIG. 3A to 3E, under the condition where the memory cell 10 is sufficiently stable, in the example, i.e., in the semiconductor memory device according to the present embodiment, the potential of the word line WL does not excessively lower. As illustrated, in the present embodiment, under the condition where the stability of the memory cell 10 is sufficient, the reduction of the potential of the word line WL is relatively small, and the read speed and the write speed never excessively lower.

As seen from such simulation result, according to the present embodiment, under the condition where the stability of the memory cell 10 is low, the potential of the word line WL can be sufficiently lowered. Under the condition where the stability of the memory cell 10 is sufficient, the potential of the word line WL never excessively lowers, and the write speed and the read speed never excessively lower.

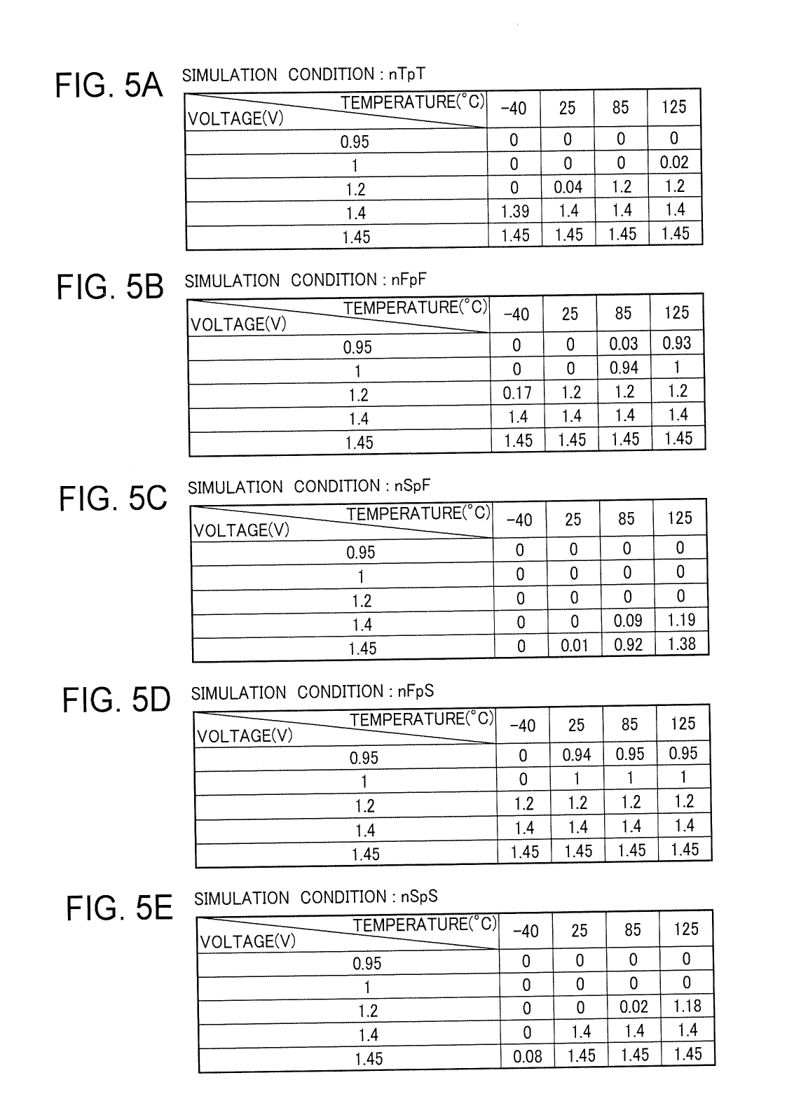

FIGS. 5A to 5E are the results of the simulations of the potential of the output of the inverter 38 in the semiconductor memory device according to the present embodiment, i.e., the potential of the gate of the N-channel transistor 44. In the simulation, the number of the N-channel transistors 22 parallelly arranged was six.

FIG. 5A illustrates the case that both the speed of the N-channel transistor and the speed of the P-channel transistor are standard. FIG. 5B illustrates the case that the speed of the N-channel transistor is higher than standard, and the speed of the P-channel transistor is higher than standard, FIG. 5C illustrates the case that the speed of the N-channel transistor is lower than standard, and the speed of the P-channel transistor is higher than standard. FIG. 5D illustrates the case that the speed of the N-channel transistor is higher than standard, and the speed of the P-channel transistor is lower than standard. FIG. 5E illustrates the case that both the speed of the N-channel transistor and the speed of the P-channel transistor are lower than standard.

When the N-channel transistor is slow, and the P-channel transistor is fast, the inverter 32 is not easily invertible under the condition that the ambient temperature is high, and the power source voltage is high. Accordingly, when the N-channel transistor is slow, and the P-channel transistor is fast, it is important that the inverter 32 surely inverts under the condition that the ambient temperature is high, and the power source voltage is high.

As seen in FIG. 5C, when the N-channel transistor is slow, and the P-channel transistor is fast, the output voltage of the inverter 32 is H level under the condition that the ambient temperature is high, and the power source voltage is high. This means that the compensating circuit 24 surely operates even under the condition that the ambient temperature is high, and the power source voltage is high.

When the N-channel transistor is fast, and the P-channel transistor is slow, the inverter 32 is invertible under the condition that the ambient temperature is low, and the power source voltage is low. Accordingly, when the N-channel transistor is fast, and the P-channel transistor is slow, it is important that the inverter 32 does not invert surely under the conditions that the ambient temperature is low, and the power source voltage is low.

As seen in FIG. 5D, when the N-channel transistor is fast, and the P-channel transistor if slow, the output voltage of the inverter 32 is L level under the conditions that the ambient temperature is low, and the power source voltage is low. This means that the compensating circuit 24 does not operate under the conditions that the ambient temperature is low, and the power source voltage is low.

As seen from such simulation result, the semiconductor memory device according to the present embodiment can also be good and highly reliable.

As described above, according to the present embodiment, the compensating circuit 24 which lowers the potential of the word line WL, based on rises of the ambient temperature and the power source voltage VDD is provided. Accordingly, when the ambient temperature and the power source voltage VDD become relatively high, i.e., when the stability of the memory cell 10 lowers, the potential of the word line WL can be sufficiently lowered, and the breakage of the information stored in the memory cell 10 can be surely prevented. When the ambient temperature and the power source voltage VDD are relatively high, sufficiently lowering the potential of the word line WL by the compensating circuit 24 never excessively lowers the read speed and the write speed, and no special problem takes place. On the other hand, when the rises of the ambient temperature and the power source voltage VDD are relatively low, i.e., when the stability of the memory cell 10 is sufficient, the compensating circuit 24 does not operate, and the potential of the word line WL never excessively lowers. Thus, the semiconductor memory device according to the present embodiment can be good and highly reliable.

### [b] Second Embodiment

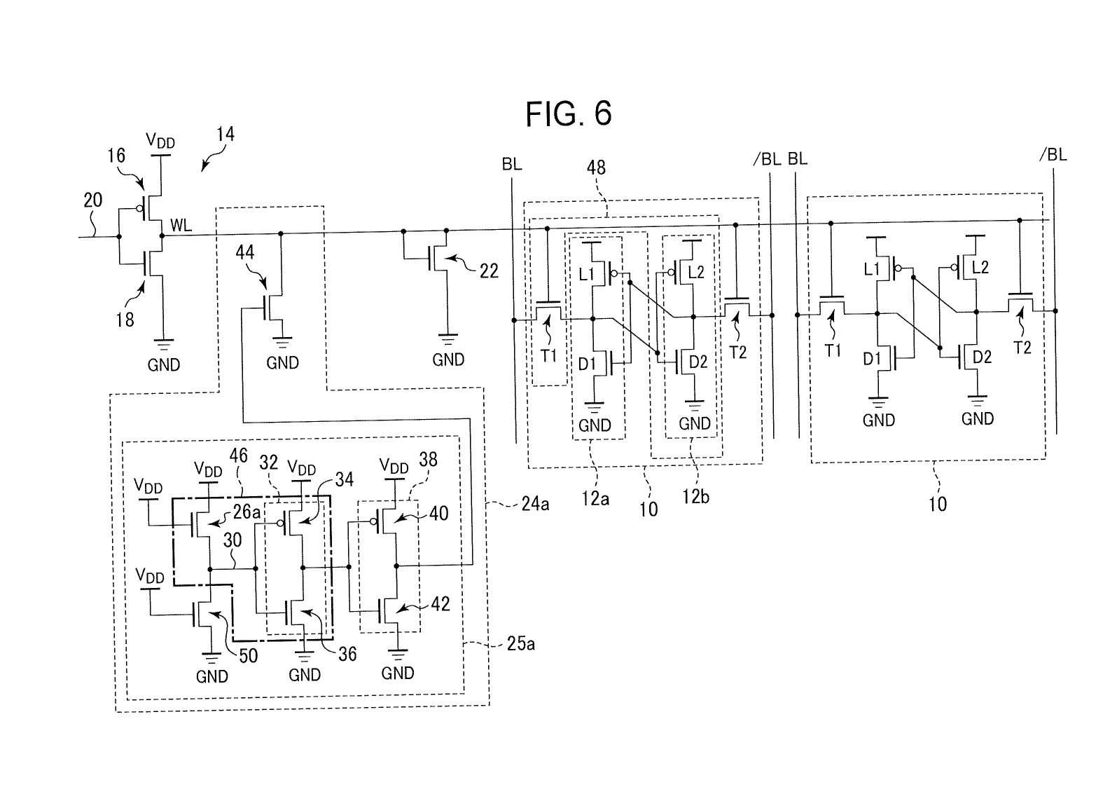

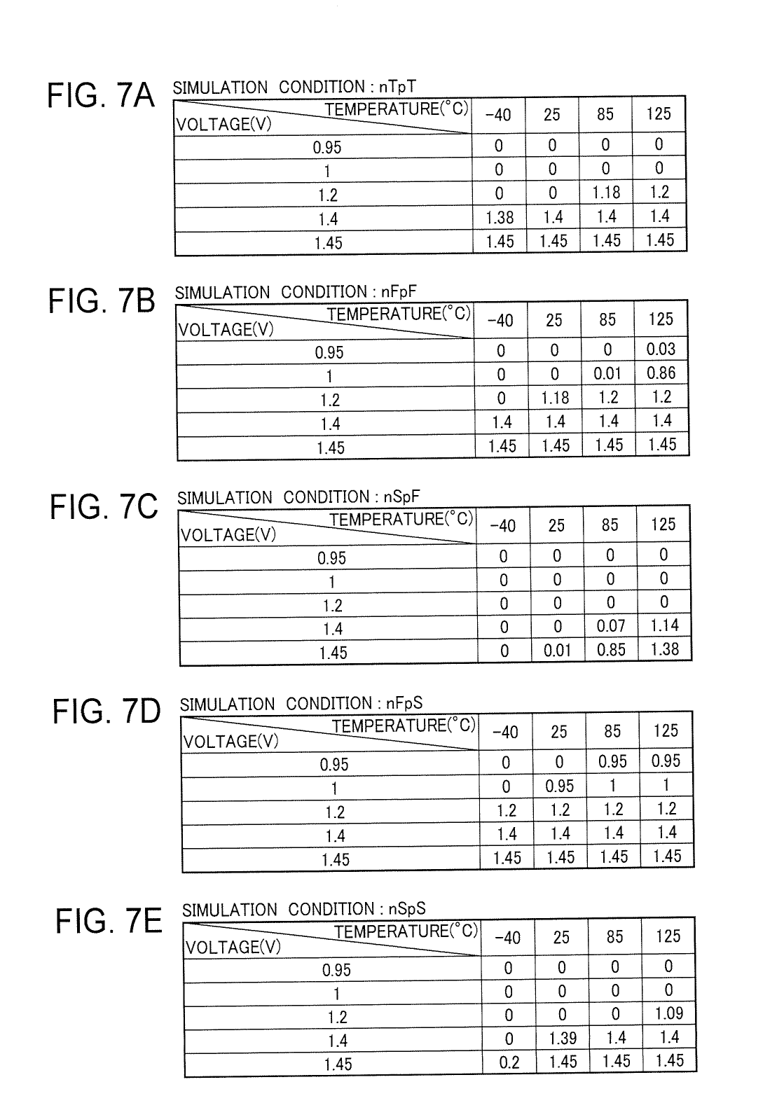

The semiconductor memory device according to a second embodiment will be described with reference to FIGS. 6 to 7E. FIG. 6 is the circuit diagram of the semiconductor memory device according to the present embodiment. The same members of the present embodiment as those of the semiconductor memory device according to the first embodiment illustrated in FIGS. 1 to 5E are represented by the same reference numbers not to repeat or to simplify the description.

The semiconductor device according to the present embodiment has the first stage of the control circuit 25a formed by an N-channel transistor 26a and an N-channel transistor 50 serially connected.

As illustrated in FIG. 6, on the first stage of the control circuit 25a, an N-channel transistor 26a and a N-channel transistor 50 serially connected is provided. For example, a plurality of N-channel transistors 26a are parallelly arranged. In FIG. 6, one of the plural N-channel transistors 26a parallelly arranged is illustrated. The respective plural parallelly arranged N-channel transistors 26a have the gates and the drains connected to the power source voltage VDD. The source of the N-channel transistor 50 is connected to the ground voltage GND. The gate of the N-channel transistor 50 is connected to the power source voltage VDD. The source of the N-channel transistor 26a and the drain of the N-channel transistor 50, i.e., a node 30 is connected to the input terminal of the inverter 32.

The gate width of the N-channel transistor 26a is set at, e.g., about 1.4 μm. The gate width of the N-channel transistor 50 is set at, e.g., about 0.1 μm.

The gate width of the N-channel transistors 26a, 50 is not limited to the above and can be suitably so set that the potential of the node 30 is a desired potential. The number of the N-channel transistor 26a parallelly arranged is not limited to two and can be suitably so set at the potential of the node 30 is a desired potential.

In the present embodiment as well, when the ambient temperature and the power source voltage VDD are relatively low, the potential of the node 30 is lower than the logic threshold potential of the inverter 32. Accordingly, the output of the inverter 32 becomes H level, and he output of the inverter 38 becomes L level. Thus, when the ambient temperature and the power source voltage VDD are relatively low, the N-channel transistor of the control circuit 25a turned OFF, and the potential of the word line WL is lowered by the N-channel transistor 22 alone.

When the ambient temperature and the power source voltage VDD are relatively high, the potential of the node 30 becomes higher than the logic threshold potential of the inverter 32. Accordingly, the potential of the inverter 32 becomes L level, the output of the inverter 38 becomes H level, and the N-channel transistor of the control circuit 25a turned ON. Thus, in the present embodiment as well, when the ambient temperature and the power source voltage VDD are relatively higher, the cooperation of the N-channel transistor 22 and the N-channel transistor 44 of the compensating circuit 24a sufficiently lowers the potential of the word line WL.

When the semiconductor memory device according to the present embodiment is designed, a simulation, e.g., Monte Carlo simulation or others, is suitably performed, and suitable values of the gate width, etc. of the transistors are given.

As described above, the semiconductor device according to the present embodiment is constituted.

(Evaluation Result)

The result of the evaluation of the semiconductor memory device according to the present embodiment will be explained with reference to FIGS. 7A to 7E.

FIGS. 7A to 7E illustrates the result of the simulation of the potential of the output of the inverter 38, i.e., the potential of the gate of the N-channel transistor 44 of the semiconductor memory device according to the present embodiment. For the simulation, the number of the N-channel transistor 22 parallelly arranged was six.

FIG. 7A illustrates the case that both the speed of the N-channel transistor and the speed of the P-channel transistor are standard. FIG. 7B illustrates the case that the speed of the N-channel transistor is higher than standard, and the speed of the P-channel transistor is also higher than standard. FIG. 7C illustrates the case that the speed of the N-channel transistor is lower than standard, and the speed of the P-channel transistor is higher than standard. FIG. 7D illustrates the case that the speed of the N-channel transistor is higher than standard, and the speed of the P-channel transistor is lower than standard. FIG. 7E illustrates the case that both the speed of the N-channel transistor and the speed of the P-channel transistor are lower than standard.

As seen in FIG. 7A to 7E, under the condition that the ambient temperature is high, and the power source voltage is high, the output voltage of the inverter 38 is H level. Accordingly, in the present embodiment, under the condition which lowers the stability of the memory cell 10, the N-channel transistor 44 of the compensating circuit 24a is turned ON, and the cooperation of the N-channel transistor 44 of the compensating circuit 24a and the N-channel transistor 22 sufficiently lowers the potential of the word line WL. Thus, the breakage of the information stored in the memory cell 10 can be surely prevented.

On the other hand, when the ambient temperature is low, and the power source voltage VDD is low, the N-channel transistor 44 of the compensating circuit 24a is OFF, and the potential of the word line WL is lowered by the N-channel transistor 22 alone. As described above, in the present embodiment, under the conditions where the memory cell 10 is stable, the potential of the word line WL never excessively lowers, and the read speed, the write speed, etc. never excessively lower.

As seen from such simulation result, the semiconductor memory device according to the present embodiment as well can be good and highly reliable.

As described above, in the present embodiment as well, when the ambient temperature and the power source voltage VDD are relatively high, the compensating circuit 24a operates, and the potential of the word line WL can be sufficiently lowered, and the erroneous rewrite of the information stored in the memory cell 10 can be prevented. On the other hand, in the present embodiment as well, when the ambient temperature and the power source voltage VDD are relatively low, the compensating circuit 24a does not operate, and the potential of the word line WL is never excessively lowered, and the read speed and the write speed are never excessively lowered. Thus, the semiconductor memory device according to the present embodiment can be good and highly reliable.

### [c] Third Embodiment

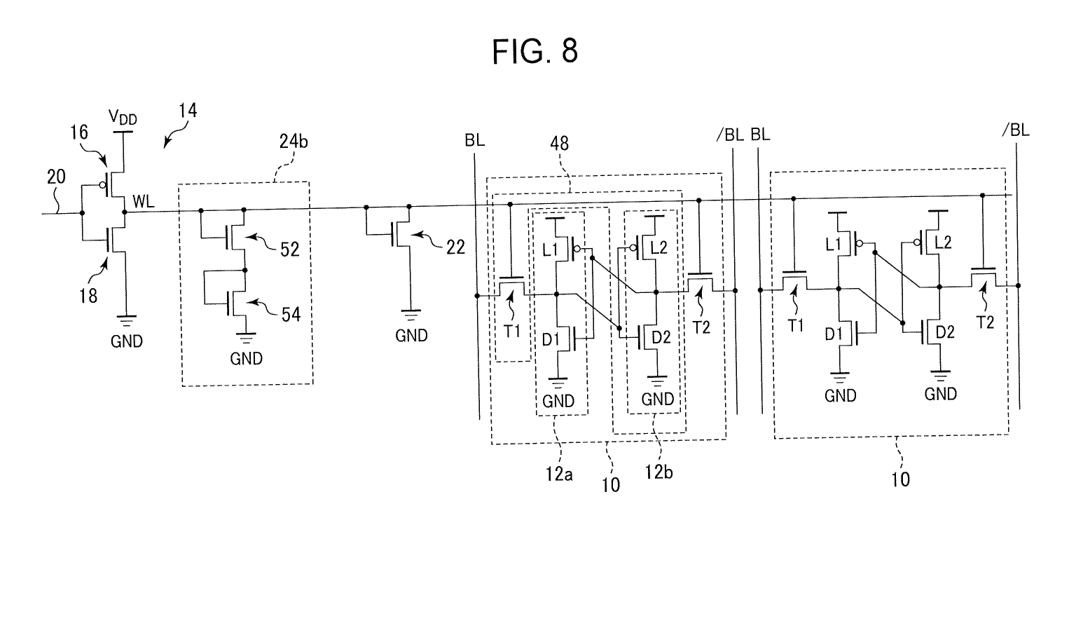

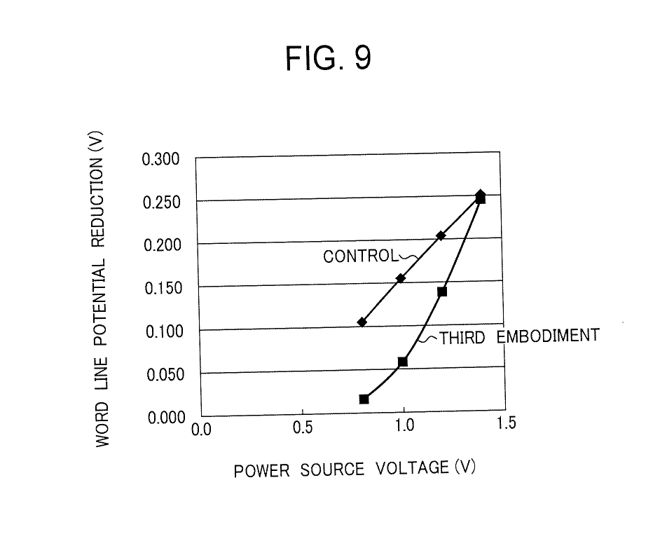

The semiconductor memory device according to a third embodiment will be described with reference to FIG. 8 and FIG. 9. FIG. 8 is the circuit diagram of the semiconductor memory device according to the present embodiment. The same members of the present embodiment as those of the semiconductor memory device according to the first or the second embodiment illustrated in FIGS. 1 to 7E are represented by the same reference numbers not to repeat or to simplify the description.

In the semiconductor memory device according to the present embodiment, the compensating circuit 24b is formed by an N-channel transistor 52 and an N-channel transistor 54 serially connected.

The compensating circuit 24b is connected to the word line WL. The compensating circuit 24b is formed by the N-channel transistor 52 and the N-channel transistor 54 serially connected. The gate and the drain of the N-channel transistor 52 are connected to the word line WL. The gate and the drain of the N-channel transistor 54 are connected to the source of the N-channel transistor 52, and the source of the N-channel transistor 54 is connected to the ground potential GND.

The gate width of the N-channel transistor 52 is set at, e.g., about 100 nm. The gate width of the N-channel transistor 54 is set at, e.g., about 100 nm.

As the gate width of the N-channel transistors 52, 54 is set larger, the reduction of the potential of the word line WL tends to be larger. Accordingly, the gate width of the N-channel transistors 52, 54 may be suitably so set that the reduction of the potential of the word line WL becomes a desired reduction.

When the ambient temperature and the power source voltage are relatively low, the reduction of the potential of the word line WL by the N-channel transistor 22 and the compensating circuit 24b is relatively small.

On the other hand, when the ambient temperature and the power source voltage VDD are relatively high, the reduction of the potential of the word line WL by the N-channel transistor 22 and the compensating circuit 24b is relatively large.

For designing the semiconductor memory device according to the present embodiment, a simulation, e.g., Monte Carlo Simulation or others, is suitably performed, and suitable values of the gate width of the transistors, etc. are given.

As described above, the semiconductor memory device according to the present embodiment is constituted.

(Evaluation Result)

The result of the evaluation of the semiconductor memory device according to the present embodiment will be described with reference to FIG. 9.

FIG. 9 is the graph of the result of the simulation of the reduction of the potential of the word line. In FIG. 9, the power source voltage is taken on the horizontal axis, and on the vertical axis, the reduction of the potential of the word line WL is taken. In FIG. 9, the ♦ plot indicates the case of the semiconductor memory device according to the control illustrated in FIG. 2. In FIG. 9, the ▪ plot indicates the case of the semiconductor memory device according to the present embodiment.

As illustrated in FIG. 9, in both cases, as the power source voltage VDD rises, the reduction of the potential of the word line WL increases.

In the semiconductor memory device according to the present embodiment, when the power source voltage VDD is relatively low, the reduction of the potential of the word line WL is much smaller relative to that of the control.

In the semiconductor memory device according to the present embodiment, when the power source voltage VDD becomes relatively higher, the reduction of the potential of the word line WL becomes sufficiently large as well as in the control.

In the control, even when the source potential VDD is relatively low, the reduction of the potential of the word line WL is relatively large, and there is a risk that the write speed and the read speed will be lowered.

In contrast to this, in the present embodiment, when the power source voltage VDD is relatively low, the reduction of the potential of the word line WL is sufficiently small, and the decease of the write speed and the read speed can be surely prevented. When the power source voltage VDD becomes high, the reduction of the potential of the word line WL becomes sufficiently large, and the breakage of the information written in the memory cell 10 can be surely prevented.

As described above, the compensating circuit 24b may be formed by the N-channel transistor 52 and the N-channel transistor 54 serially connected. In the present embodiment as well, when the ambient temperature and the power source voltage VDD are relatively high, the potential of the word line WL can be sufficiently lowered, and the erroneous rewrite of the information stored in the memory cell 10 can be prevented. In the present embodiment as well, when the ambient temperature and the power source voltage VDD are relatively low, the potential of the word line WL never excessively lowers, and the read speed and the write speed never excessively lower. Thus, the semiconductor memory device according to the present embodiment as well can be good and highly reliable.

### Modified Embodiments

The present invention is not limited to the above-described embodiments and can cover other various modifications.

For example, in the first embodiment, in the compensating circuit 24, the circuit 46 formed by the transistors 26, 34, 36 is provided corresponding to the circuit 48 formed by the transistors T1, L1, D1 of the memory cell 10. In the second embodiment, in the compensating circuit 24, the circuit 46 formed by the transistors 26a, 34, 36 is provided corresponding to the circuit 48 formed by the transistors T1, L1, D1 of the memory cell 10. However, the circuit provided in the compensating circuit 24 may not be a circuit corresponding to the circuit 48 formed by the transistors T1, L1, D1 of the memory cell 10. A compensating circuit which turns OFF the transistor 44 when the memory cell 10 is sufficiently stable and turns ON the N-channel transistor 44 when the stability of the memory cell 10 lowers may be provided.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor memory device comprising:
a memory cell of static type;
a word line connected to the memory cell;
a word driver driving the word line; and
a compensating circuit including a first transistor of N-channel type having a drain connected to the word line and a source to be connected to a ground potential, and a control circuit connected to the first transistor and changing the first transistor from an OFF state to an ON state based on a rise of an ambient temperature or a rise of a power source voltage to thereby lower a voltage of the word line.

2. The semiconductor memory device according to claim 1, wherein
the control circuit comprises:
a second transistor of N-channel type having a gate and a drain to be connected to the power source voltage;
a third transistor having one of source/drain connected to a source of the second transistor and the other of the source/drain to be connected to the ground potential; and
a first inverter including a fourth transistor of P-channel type having a gate connected to the source of the second transistor and a source to be connected to the power source voltage and a fifth transistor of N-channel type having a gate connected to the source of the second transistor, a drain connected to a drain of the fourth transistor and a source to be connected to the ground potential.

3. The semiconductor memory device according to claim 2, wherein
the memory cell comprises:
a sixth transistor of N-channel type having a gate connected to the word line and one of source/drain connected to a bit line; and
a second inverter including a seventh transistor of P-channel type having a gate connected to the other of the source/drain of the sixth transistor and a source to be connected to the power source voltage, and an eighth transistor of N-channel type having a gate connected to the other of the source/drain of the sixth transistor, a drain connected to a drain of the seventh transistor and a source to be connected to the ground potential,
a first current driving force ratio which is a ratio of a current driving force of the fifth transistor to a current driving force of the second transistor is smaller than a second current driving force ratio of a current driving force of the eighth transistor to a current driving force of the sixth transistor.

4. A semiconductor memory device comprising:
a memory cell of static type;
a word line connected to the memory cell;
a word driver driving the word line; and
a compensating circuit including a first transistor of N-channel type having a gate and a drain connected to the word line, and a second transistor of N-channel type having a gate and a drain connected to a source of the first transistor and a source to be connected to a ground potential.

5. The semiconductor memory device according to claim 1, further comprising
a ninth transistor of N-channel type having a gate and a drain connected to the word line and a source to be connected to the ground potential and lowering a potential of the word line.

6. The semiconductor memory device according to claim 4, further comprising
a ninth transistor of N-channel type having a gate and a drain connected to the word line and a source to be connected to the ground potential and lowering a potential of the word line.
